(19) United States
(12) Patent Application Publication
(10) Pub. No.: US 2024/0012197 A1
(43) Pub. Date: Jan. 11, 2024

(54) LIGHT ISOLATING ARRAYS

(71) Applicants: SCHOTT Coporation, Rye Brook, NY (US); SCHOTT AG, Mainz (DE)

(72) Inventors: Oliver Sohr, Mainz (DE); Sebastian Leugner, Gernsheim (DE); Kevin Tabor, Webster, MA (US); Michael Dargie, Southbridge, MA (US); Elisabeth Han, Shrewsbury, MA (US)

(73) Assignees: SCHOTT Corporation, Rye Brook (DE); SCHOTT AG, Mainz (DE)

(21) Appl. No.: 18/252,377

(22) PCT Filed: Nov. 16, 2021
(86) PCT No.: PCT/US2021/072415

§ 371 Date: May 10, 2023

Related U.S. Application Data
(60) Provisional application No. 63/118,650, filed on Nov. 26, 2020.
(60) Provisional application No. 63/186,184, filed on May 10, 2021.
(60) Provisional application No. 63/261,468, filed on Sep. 22, 2021.

(51) Int. Cl. G02B 6/10

(52) U.S. Cl. CPC G02B 6/10

(57) ABSTRACT

The present disclosure relates to light isolating arrays (can also be called “light pipes” or “light pipe arrays”) that enable high transmission efficiency and isolation of light from one location, for example a lens, to another location, for example an array of photodetector diodes (each a “PD”). The light isolating arrays can provide optical isolation of the input light and can eliminate cross talk thus enhancing the resolution via increased contrast of the incoming signal. The light isolating arrays can also protect the PD's from contamination when used in outdoor devices.

### CROSS REFERENCE TO RELATED APPLICATIONS

This is a national stage entry of PCT application no. PCT/US2021/072415, entitled“LIGHT ISOLATING ARRAYS”, filed November 16, 2021, which is incorporated herein by reference. PCT application No. PCT/US2021/072415 claims priority to US provisional patent applications nos. U.S. 63/118,650, filed Nov. 26, 2020, U.S. 63/186,184, filed May 10, 2021, and U.S. 63/261,468, filed Sep. 22, 2021, which are incorporated herein by reference.

### BACKGROUND OF THE DISCLOSURE

### 1. Field of the Disclosure

The present disclosure relates to light isolating arrays (can also be called “light pipes” or “light pipe arrays”) that enable high transmission efficiency and isolation of light from one location, for example a lens, to another location, for example an array of photodetector diodes (each a “PD”). The light isolating arrays can provide optical isolation of the input light and can eliminate cross talk thus enhancing the resolution via increased contrast of the incoming signal. The light isolating arrays can also protect the PD's from contamination when used in outdoor devices.

### 2. Background of the Disclosure

Currently available light isolating arrays utilize low numerical aperture fiber optic faceplates which can suffer from oversampling as a result of having too many fibers for each photodiode detector. Other technologies, such as open mechanical apertures, do not allow for optical coatings and can suffer from debris contamination in the openings.

### SUMMARY OF THE DISCLOSURE

The light isolating arrays of the present disclosure can alleviate many of the problems of current light isolating arrays. The light isolating arrays of the present disclosure can collect and isolate light from one location to another location while providing optical isolation of the input light and eliminating or significantly minimizing cross talk thus enhancing the resolution via increased contrast of the incoming signal.

In some embodiments, a light isolating array comprises a transparent material having a thickness, a light inlet face, a light outlet face, a side face, a plurality of light conducting conduits and a plurality of optical isolation channels. The plurality of light conducting conduits can have a horizontal light inlet surface that is substantially parallel to the light inlet face, a horizontal light outlet surface that is substantially parallel to the light outlet face, and a vertical side wall that is substantially parallel to the side face. The plurality of optical isolation channels can be openings in the material between the light conducting conduits and can extend from the light inlet face or the light outlet face from about 5% of the total thickness to 100% or less of the total thickness of the material. Each optical isolation channel can have a channel bottom and channel side walls (one of the channel side walls can be the same surface as the vertical side wall of a light conducting conduit). An optical isolation material can be applied to the channel bottom and/or the channel side walls . The light isolating array can transmit light through each light conducting conduit from the horizontal light inlet surface to the horizontal light outlet surface (or in the opposite direction) while the optical isolation material can substantially prevent the light from traveling between the individual light conducting conduits. The light conducting conduits can be a single solid material, for example solid glass or solid polymer, that transfers the light through the material with high efficiency.

### BRIEF DESCRIPTION OF THE FIGURES

FIGS. 1 is a perspective view of a light isolating array according to an embodiment of the invention.

FIG. 2 is a side view of a light isolating array according to an embodiment of the invention.

FIG. 3A shows an individual light conducting conduit according to an embodiment of the invention.

FIG. 3B shows a plurality of light conducting conduits according to an embodiment of the invention.

FIG. 3C shows a plurality of light conducting conduits according to an embodiment of the invention.

FIG. 4 shows an individual light conducting conduit according to an embodiment of the invention.

FIG. 5 shows a light isolating array according to an embodiment of the invention.

FIG. 6 shows a light isolating array according to an embodiment of the invention.

FIG. 7 shows a light isolating array according to an embodiment of the invention.

FIG. 8 is a side view of an optical isolation channel according to an embodiment of the invention.

FIG. 9 shows an embodiment of the invention where the optical isolation channels are in the shape of discontinuous rings.

### DETAILED DESCRIPTION OF THE DISCLOSURE

The light isolating array can comprise a transparent material having a thickness, a light inlet face, a light outlet face, a side face, a plurality of light conducting conduits and a plurality of optical isolation channels. The light isolating array including the light conducting conduits can be made from any material that has high transmission (for example greater than 90%) in the wavelengths of interest for the emitter and PD/sensor performance, for example they can be made from a plate-like material composed of a single glass material or a single polymer material. The typical transmission wavelength range of interest for PD's is approximately 350 2,500 nm, ideally suited for transmitting typical 905 nm, 1,310 nm and 1,550 nm laser emission wavelengths. Optical glass having a transmission of about 97 to about 99% in the visible and near infrared spectrums is a suitable example.

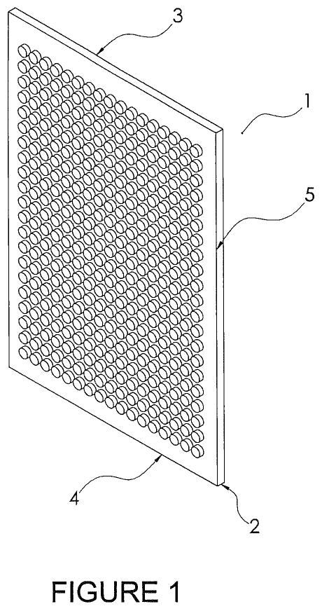

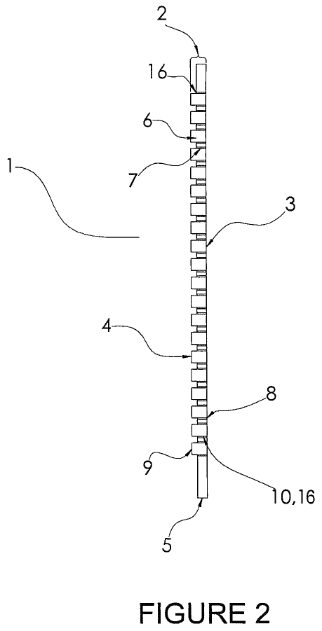

FIGS. 1 and 2 show a light isolating array 1 made from a transparent plate-like material having a thickness 2, a light inlet face 3, a light outlet face 4, a side face 5, a plurality of light conducting conduits 6 and a plurality of optical isolation channels 7. A plate-like material is a material that has a length and width that is substantially greater than its depth, for example a flat glass sheet. Suitable transparent materials include most glass and polymer materials that transmit more than 90% of light in the desired wavelengths. Although FIGS. 1 and 2 show the light conducting conduits and the optical isolation channels 7 on outlet face 4 side only, the light conducting conduits and the optical isolation channels 7 can additionally or alternatively be located on the light inlet face 3 side. In addition, the optical isolation channels 7 can extend through the entire thickness of the material.

A plurality of optical isolation channels 7 can be formed in the light isolating array 1 to create the light conducting conduits 6. Suitable processes to form the optical isolation channels 7 include laser filamentation followed by etching. In such processes, a laser is applied to a precursor material that does not have any optical isolation channels, for an example a flat glass sheet. The lasering and subsequent etching process remove select portions of the glass precursor material in a precise manner to create the plurality of optical isolation channels. The plurality of optical isolation channels are essentially empty spaces that are created by removing portions of the precursor material and which define the side boundaries of the light conducting conduits 6. In other words, the light conducting conduits 6 are segments of the precursor material that remain after certain segments of the precursor material are removed to create the plurality of optical isolation channels 7.

FIGS. 2, 3A, 3B and 4 show a plurality of light conducting conduits 6 each having a horizontal light inlet surface 8 that is substantially parallel to the light inlet face 3 of the transparent plate like material, a horizontal light outlet surface 9 that is substantially parallel to the light outlet face 4, and a vertical side wall 10 that is substantially parallel to the side face 5. The plate like material including the light conducting conduits can be formed from a single solid material and can be able to transfer a focused light beam through the plate like material and through the light conducting conduits with high efficiency.

The individual light conducting conduits can have an optical isolation material applied to a surface thereof or to the optical isolation channels to isolate each individual light conducting conduit from its neighboring light conducting conduit thereby providing high contrast and high resolution. The optical isolation material can be for example an opaque material, an absorptive material, and/or a reflective material. The materials can be applied in one or more layer combinations and/or as a filler for the optical isolation channels. The light that has been transmitted through the light conducting conduits can be guided toward sensors/detectors without significant distortion of the optical wavefront provided by the lens or lens array. The degree of optical isolation can be measured by the amount of light damping.

The laser filamentation process can control the dimensions of the filament that is formed in the precursor material. Multiple consecutively arranged individual filaments can be formed and subsequently etched to connect the filaments to form the optical isolation channels.

The thickness of the light isolating array and transparent material after lasering and etching may correspond to the thickness of the precursor material prior to lasering and etching. This is because the light conducting conduits are segments of the precursor material that remain in the light isolating array after segments of the precursor material are removed to form the optical isolation channels. In many cases, the horizontal light outlet surface of each light conducting conduit is coplanar with the light outlet face of the precursor material prior to lasering and etching, and in those cases the thickness of the light isolating array is measured from the horizontal light outlet surface of the light conducting conduits (which is coplanar to the light outlet face of the precursor material) to the light inlet face of the light isolating array. In embodiments where the optical isolation channels do not extend through the entire thickness of the light isolating array, a portion of the precursor material remains beneath the bottom of the optical isolation channels. A segment of the thickness of the light isolating array would exist from the light inlet face of the light isolating array to the bottom of the optical isolation channels, and viewed from the side of the light isolating array, this segment may look similar to a support for the light conducting conduits (see FIG. 2 for example). The thickness of this segment is the thickness of the light isolating array minus the depth of the optical isolation channels.

The light isolating array and precursor material can have any thickness suitable for the intended application. In some embodiments, the thickness can be about 0.1 to about 50 mm, about 0.1 to about 30 mm, about 0.1 to about 10 mm, about 0.1 to about 5 mm, or about 0.1 to about 1 mm.

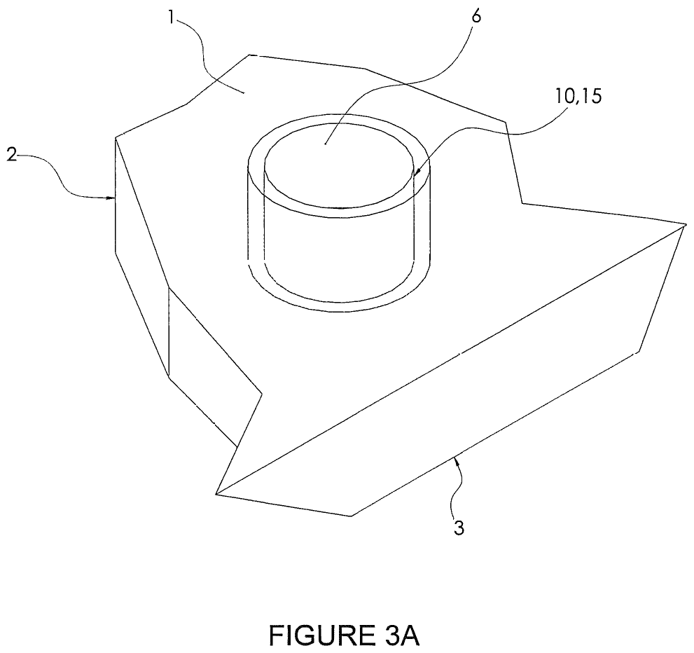

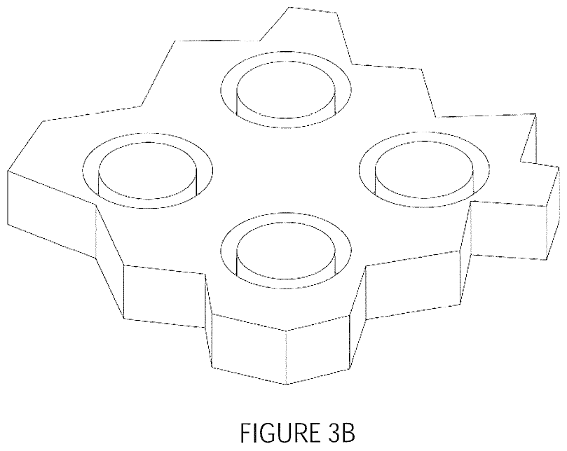

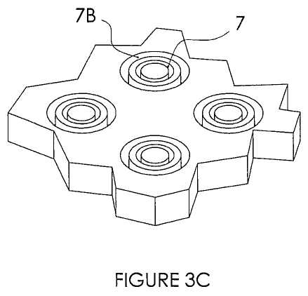

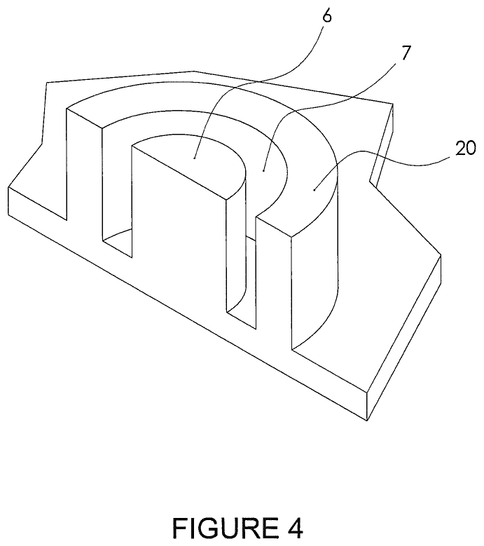

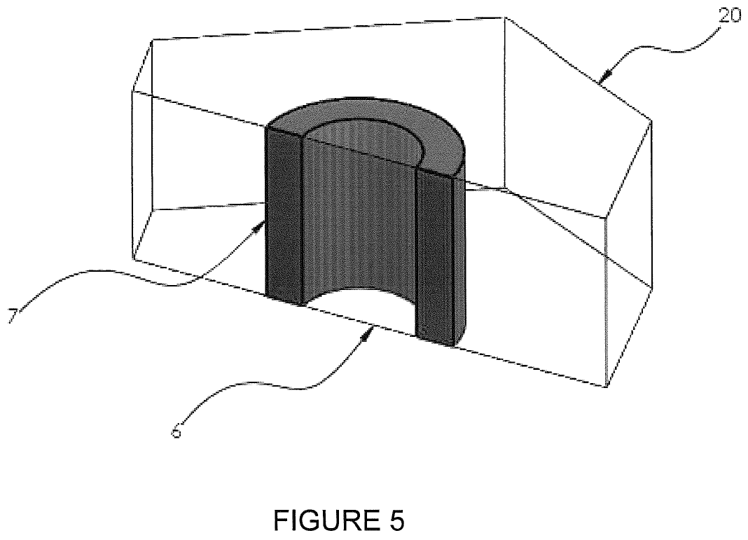

It is not necessary for the optical isolation channels to extend completely through the entire thickness of the light isolating array, although it may be desirable in some embodiments for the optical isolation channels to extend completely through the thickness. To make the optical isolation channels extend completely through the thickness, the optical isolation channels can be filled with an optical isolation material to hold the light conducting conduits together, then the material the light conducting conduits can be thinned by reducing its thickness (including the including the height of the light conducting conduits) so that the optical isolation channels extend completely through the entire thickness of the substrate. In some embodiments, the optical isolation channels extend from the light inlet face or the light outlet face from about 5% of the thickness to 100% or less of the thickness of the light isolating array, from about 50% to 100% or less of the thickness of the light isolating array, or from about 80 to 100% or less of the thickness of the light isolating array. For example, the optical isolation channels 7 in FIG. 4 extend from the outlet face 4 through about 80% of the thickness. The optical isolation channels 7 in FIG. 3A and FIG. 5 extend from the outlet face 4 completely through the entire thickness.

It is not necessary for the optical isolation channels to extend completely from the vertical side wall of one light conducting conduit to the vertical side wall of another light conducting conduit. In such cases, the optical isolation channels can be considered “rings” that surround the individual light conducting conduits, as shown for example in FIGS. 3A, 3B and 4. Two or more concentric rings 7 and 7B can be provided as shown in FIG. 3C and in some embodiments the radial distance between each concentric ring is 25 μm to 100 μm. In these embodiments, the optical isolation channels should have a width that is large enough to achieve the desired light damping for the intended application, depending on the optical isolation material being used in the optical isolation channels. On the other hand, if the optical isolation channel width is too great, the structural integrity of the light isolating array could be comprised because less material would remain between each light conducting conduit.

As shown in FIGS. 3A and 3B, the lasering and etching process did not remove the portions of the light-isolating array between each optical isolation channel. In contrast, the lasering and etching process that produced the light-isolating array in FIG. 4 did remove the majority of the precursor material that existed between each optical isolation channel, to leave behind the light conducting conduit 6, the optical isolation channel 7 in the shape of a ring for example that surrounds the light conducting conduit 6, a portion 20 of the transparent precursor material (also shown as a ring in FIG. 4) that surrounds the optical isolation channel 7, and an empty space between the portion 20 and the adjacent light conducting conduit (not shown in FIG. 4).

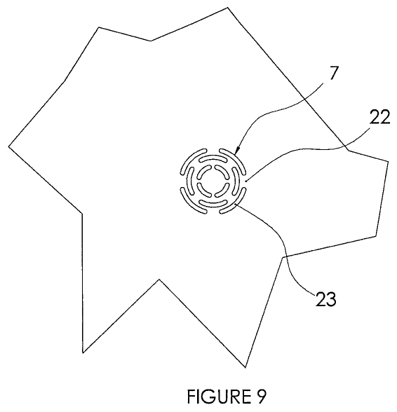

It is not necessary for the optical isolation channels to be continuous for example in the shape of a ring. FIG. 9 shows an embodiment where the optical isolation channels 7 are in the shape of discontinuous rings. Those rings have discontinuous segments 22, which when measured along the circumference created by the channels 7, the discontinuous segments 7 may alternate between continuous segments 2. Also, FIG. 9 shows that each discontinuous and concentric optical isolation channel 7 can be surrounded by one or more discontinuous and concentric optical isolation channels 7. The continuous and discontinuous segments minimize the amount of glass that is removed from the initial starting material which minimizes the amount of glass strength that is lost.

In order to minimize the amount of light that may escape through the discontinuous segments, the segments of two adjacent optical isolation channels 7 may be offset from each other as shown in FIG. 9 so that the escaping light will likely be dampened by either the first or the second optical isolation channel.

In some embodiments, the optical isolation channels can have a diameter of about 0.01 to about 10 mm or about 0.05 to about 5 mm (the channel diameter is measured from one side face of the light isolating array to the opposite side face), a width of about 0.001 to about 5 mm, about 0.001 to about 2 mm or about 0.015 to about 1 mm (the channel width is measured as the distance between the channel side walls), and a depth of about 0.01 to about 30 mm, or about 0.01 to about 10 mm, or about 0.05 to about 30 mm, or about 0.05 to about 10 mm, or about 0.05 to about 5 mm (the channel depth is measured as the length of the vertical side wall 10 of the light conducting conduits). Each individual optical isolation channel can have different dimensions compared to the other individual optical isolation channels. In addition, in embodiments where the optical isolation channel width extends from one light conducting conduit to another, the optical isolation channel width is the distance between the vertical side walls of those light conducting arrays.

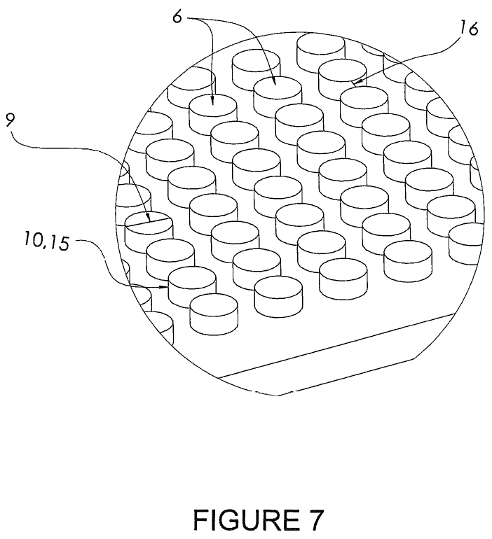

The initial depth and width of the optical isolation channels can be created by the laser and subsequently enlarged toward their final values by etching. FIGS. 2, 3A and 7 show a light conducting array with optical isolation channels 7 having a channel depth 15, a channel width 16 and a channel diameter 17.

The total number of optical isolation channels and corresponding light conducting conduits that are created is not particularly limited. It may be desirable to structure the periodicity and dimensions of the optical isolation channels and the corresponding light conducting conduits to match the periodicity and dimensions of PD arrays in LiDAR sensors so that light transmitted through each light conducting conduit is received by the corresponding PD. For example, if the PD array is a grid of 100×100 PD's with a certain PD size and spacing, then the light isolating array of the current invention can be structured with a 100×100 array of discrete light conducting conduits that each transmit light to a discrete corresponding PD. This numerical and dimensional correspondence between the light isolating array and the PD array can provide optical isolation of the input light and can eliminate cross talk thus enhancing the resolution via increased contrast of the incoming signal.

In some embodiments, a suitable number of optical isolation channels is formed to result in about 0.25 to about 10,000, about 0.25 to about 100, or about 0.25 to about 5 light conducting conduits per square millimeter of the light isolating array.

The light conducting conduits that remain after forming the optical isolation channels by removing portions of the precursor material are not limited in shape and size. The light conducting conduits when viewed from their outlet surfaces can be round, square or hexagonal for example, and it is possible to create any shape that is desirable for the corresponding PD's. The light conducting conduits can be arranged over the substantial majority of the light inlet face or the light outlet face of the material or over any portion thereof. In some embodiments, each light conducting conduit can have a height of about 100 μm to about 50 mm, about 100 μm to about 30 mm, about 100 μm to about 10 mm, or about 100 μm to about 5 mm, and a diameter or other similar dimension of about 10 μm to about 10 mm or about 10 μm to about 5 mm. Each individual light conducting conduit can have different dimensions compared to the other individual light conducting conduits. FIGS. 2 and 3A show a light conducting array with light conducting conduits 6 having a vertical side wall 10 whose length is the light conducting conduit height and a horizontal outlet surface 9 where each individual conduit has conduit width 21.

The aspect ratio (the ratio of the height to the diameter) of each light conducting conduit can be within a range of about 100:1 to about 1:1, or about 100:1 to about 10:1, or about 30:1 to about 10:1, or about 30:1 to about 5:1 for example. High aspect ratios can be more challenging for creating the optical isolation channels and subsequent coating, meaning that laser filamentation and etching may be more desirable processes relative to photolithography which could produce light conducting conduits with undesirable tapers.

The light isolating arrays of the current invention are not required to have a light inlet face that is parallel to the light outlet face. The light isolating arrays can be curved which can be particularly useful to accommodate PD's on 3 dimensional surfaces, for example each light conducting conduit (and the corresponding light inlet face and/or light outlet face) can be tilted to guide the light on an angle toward the corresponding PD, for example within 80 to 100° relative to the PD.

The operation of the laser and suitable laser specifications are known to those in the art and are not particularly limited. Suitable wavelengths are 400-1,600 nm, preferably 1064/532 nm (Nd:YAG) or 1030/515 nm (Er:YAG). Pulse durations can be ultra short pulse (UKP) at 1 ns>t>50 fs with 18 bursts. The repetition rate can be 10 kHz to 2 MHz. The power can be 5 200 W on average. The energy can be 50 μJ to 40 mJ. The raw beam can be gaussian, flat top, donut or airy. The machinery can be an XYZ motiondrive with <5 μm precision/repeatability with a dual (or multiple) beam path (1 fixed optics+1 scanner) at an XY Axis speed of 100 to 2,000 mm/s and a scanner speed of 500 to 5,000 mm/s.

One possible way to form the optical isolation channels and associated light conducting conduits of the current invention is to use a laser to form an array of filaments followed by etching the filaments to enlarge and connect the filaments to form the optical isolation channels. The lasering and etching processes can even remove all of the material between the individual light conducting conduits, although the removal of so much excess material may be unnecessary for the function of the light isolating array and could weaken the structural integrity of the light isolating array. Suitable etching processes are known to those in the art and are not particularly limited. For example, liquid etching can be used with or without a lye, acid and other additives. Dry etching with plasma and steam assist can also be used.

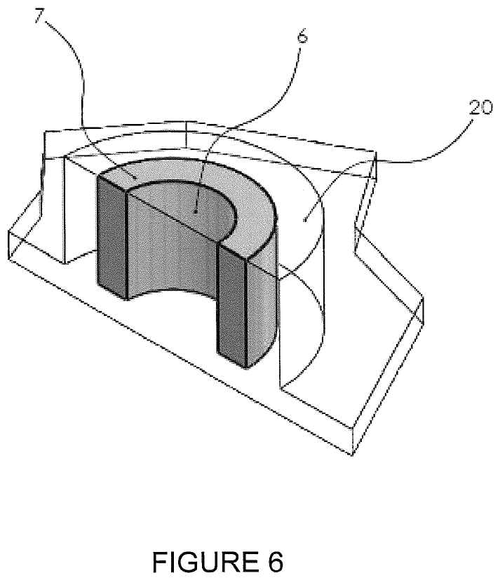

An optical isolation material, for example a coating or a filler, can be applied to one or more surfaces of the optical isolation channels or to one or more surfaces of the light conducting conduits to optically isolate each light conducting conduit, for example as shown in FIG. 6. The material can be an opaque material, an absorptive material, and/or a reflective material. An optical material can also be applied. The materials can also act as a mechanical stabilizer for the light isolating array by providing twisting and bending dampening. The opaque, absorptive and reflective materials can help contain light within each light conducting conduit and the optical material can change or enhance the functionality of the light isolating array. Other suitable materials include anti reflective (AR) and band pass (BP) coatings. The materials can be applied via known techniques.

The optical isolation material can substantially prevent the light from traveling between the individual light conducting conduits. In some embodiments, it is desirable for the optical isolation material to have a high absorbance in the wavelength region that is sensed by the target PD so that the relevant wavelengths of light do not contaminate an adjacent light conducting conduit and PD. In this regard, it may be desirable for damping of light leakage from each light conducting conduit to be in the range of 10 to 150 dB, preferably 10 to 90 dB, and most preferably 30 to 65 dB. A suitable optical isolation material can be an absorptive material such as a glass frit, preferably a black glass frit, graphite, carbon black, a metal, and/or other absorbing materials, including those with an extinction coefficient (k value) above 0.01 in the relevant wavelength, such as SiC, TiN, and silicon oxycarbide. The material can contain an absorbing pigment such as a black spinel such as a manganese ferrite spinel, carbon black and/or graphite. Suitable binders for the absorbing pigments include a silicone, an organic binder (eg an epoxy, a polyurethane or an acrylic resin), and/or an inorganic organic hybrid binder (eg an ormocer).

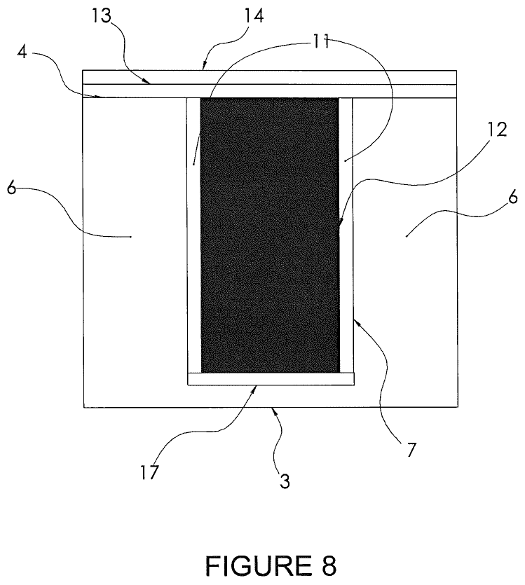

In addition to or as an alternative to an absorbing material, a reflective material can be applied to the optical isolation channels and/or to the light conducting conduits. FIG. 8 shows an embodiment having light inlet face 3, light outlet face 4, optical isolation channel 7, a reflective coating 11 applied to vertical side wall 10 of the light conducting conduits 6 (this is the same surface as the channel side wall 19) and to the channel bottom 18, an absorbing coating 12 applied to the reflective coating 11 and filling the majority of the optical isolation channel 7, a band pass filter coating 13 applied to the horizontal outlet surface 9 of the light conducting conduits 6, and an anti-reflective coating 14 applied to the band pass filter coating 13. In other embodiments, one of more of these optical isolation materials may be applied to one or more different surfaces. Some of these materials can fill the optical isolation channels to “glue” the light conducting conduits together which enhances stability and enables the facile polishing of the horizontal outlet surface 9 to be perfectly or nearly perfectly planar without breakage and while retaining the mechanical strength of the entire array. All of the described materials can be applied by known techniques, including liquid coating, gas phase deposition, and physical deposition techniques such as CVD, PE CVD, ALD and PE ALD.

Suitable absorbing materials also include high k materials that absorb light of the relevant wavelength and simultaneously support stability of the entire light isolating array structure (for example low melting metals and solder pastes; binder systems that support stability of the light array with pigments that absorb light of the relevant wavelength; and binder systems that fill the optical isolation channels and contain organic groups that can be carbonized after filling by rapid laser heating or tempering in inert atmosphere). Suitable binder systems include organic polymers (such as epoxy, polyurethanes and acrylics), silicone based polymers (such as silsesquioxanes and less crosslinked silicones), inorganic organic hybrid materials (such as ormocers) and glass frits.

Suitable reflective materials include materials that have high reflectivity in the relevant wavelength (for example metallic silver, aluminum, indium doped tin oxide and aluminum doped zinc oxide); materials with a lower refractive index than the material used for the light conducting conduits to propagate total internal reflection; and alternating low and high refractive index material layers with specific layer thickness that build a Bragg reflector for the specific wavelength to reflect (for example alternating layers of SiO₂ TiO₂ SiO₂).

The light isolating arrays of the current disclosure are useful for example as cross-talk inhibitors in man operated or autonomous vehicle collision avoidance in automobiles, trucks, and aerial vehicles such as drones, and anywhere collision avoidance is necessary. They are also useful in (multi-)spectral cameras for the selective analysis of multi-wavelength optical signals, for example, smartphones, as well as being useful in high-resolution medical applications as well as space and automotive applications. The light isolating arrays are useful in LiDAR systems and as x-ray imaging faceplates and x-ray collimations arrays and biometric sensors.

While the present disclosure has been described with reference to one or more exemplary embodiments, it will be understood by those skilled in the art that various changes may be made and equivalents may be substituted for elements thereof without departing from the scope of the present disclosure. In addition, many modifications may be made to adapt a particular situation or material to the teachings of the disclosure without departing from the scope thereof. Therefore, it is intended that the present disclosure not be limited to the particular embodiment(s) disclosed as the best mode contemplated, but that the disclosure will include all embodiments falling within the scope of the appended claims.

What is claimed is:

1. A light isolating array, comprising:
(a) a transparent material having a thickness, a light inlet face, a light outlet face, a side face, a plurality of light conducting conduits and a plurality of optical isolation channels, wherein,
(i) the plurality of light conducting conduits have a horizontal light inlet surface that is substantially parallel to the light inlet face, a horizontal light outlet surface that is substantially parallel to the light outlet face, and a vertical side wall that is substantially parallel to the side face, and
(ii) the plurality of optical isolation channels are openings in the material between the light conducting conduits and extend from the outlet face through about 5% to 100% of the thickness; and
(b) an optical isolation material applied to the vertical side wall of the plurality of light conducting conduits,
wherein the light isolating array transmits light through each light conducting conduit from the horizontal light inlet surface to the horizontal light outlet surface while the optical isolation material substantially prevents the light from traveling between the light conducting conduits.

2. The transparent array of claim 1, wherein the transparent material is comprised of single glass material or a single polymer material.

3. The transparent array of claim 1, wherein the light conducting conduits transmit at least 90% of light at a wavelength of 350 to 2,500 nm.

4. The transparent array of claim 1, wherein a damping of light leakage from each light conducting conduit is in the range of 10 to 150 dB.

5. The transparent array of claim 1, wherein the light isolating array comprises about 0.25 to about 5 light conducting conduits per square millimeter of the light isolating array.

6. The transparent array of claim 1, wherein the light conducting conduits have a height of about 100 μm to about 50 mm and a diameter of about 10 μm to about 10 mm.

7. The transparent array of claim 1, wherein aspect ratio of the light conducting conduits is about 30:1 to about 5:1.

8. The transparent array of claim 1, wherein the optical isolation channels extend through 100% of the thickness of the material.

9. The transparent array of claim 1, wherein the optical isolation channels extend through about 80% to 100% or less of the thickness of the material.

10. The transparent array of claim 1, wherein the horizontal light outlet surface of each light conducting conduit is coplanar with the light outlet face.

11. The transparent array of claim 1, wherein the optical isolation channels do not extend completely from the vertical side wall of one light conducting conduit to the vertical side wall of another light conducting conduit.

12. The transparent array of claim 1, wherein the optical isolation channels have a diameter of about 0.01 to about 10 mm, a width of about 0.001 to about 5 mm, and a depth of about 0.01 to about 30 mm.

13. The transparent array of claim 1, wherein the optical isolation material comprises an opaque material, an absorptive material, and/or a reflective material.

14. The transparent array of claim 1, wherein the optical isolation material comprises a light absorbing material applied on a light reflective material.

15. The transparent array of claim 1, wherein the optical isolation material is also applied to an optical isolation channel bottom.
